(19) United States
(12) Patent Application Publication
(10) Pub. No.: US 2018/0145253 A1
(43) Pub. Date: May 24, 2018

(54) Method of Forming Resistive Random Access Memory (RRAM) Cells

(71) Applicant: Silicon Storage Technology, Inc., San Jose, CA (US)

(72) Inventors: Feng Zhou, Fremont, CA (US); Xian Liu, Sunnyvale, CA (US); Steven Lemke, Boulder Creek, CA (US); Santosh Hariharan, San Jose, CA (US); Hieu Van Tran, San Jose, CA (US); Nhan Do, Saratoga, CA (US)

(21) Appl. No.: 15/727,776

(22) Filed: Oct. 9, 2017

Related U.S. Application Data
(60) Provisional application No. 62/426,114, filed on Nov. 23, 2016.

(51) Int. Cl. H01L 45/00

(52) U.S. Cl. CPC H01L 45/1608; H01L 45/1253; H01L 45/146; H01L 45/1675

(57) ABSTRACT

A method of forming a memory device includes forming a first layer of conductive material having opposing upper and lower surfaces, forming a layer of amorphous silicon on the upper surface of the first layer of conductive material, stripping away the layer of amorphous silicon, wherein some of the amorphous silicon remains in the upper surface of the first layer of conductive material, forming a layer of transition metal oxide material on the upper surface of the first layer of conductive material, and forming a second layer of conductive material on the layer of transition metal oxide material. The method smoothes the upper surface of the bottom electrode, and also provides an bottom electrode upper surface with stable material that is hard to oxidize.

### RELATED APPLICATIONS

This application claims the benefit of U.S. Provisional Application No. 62/426,114, filed on Nov. 23, 2016, and which is incorporated herein by reference.

### FIELD OF THE INVENTION

The present invention relates to non-volatile memory, and more specifically to resistive random access memory.

### BACKGROUND OF THE INVENTION

Resistive random access memory (RRAM) is a type of nonvolatile memory. Generally, RRAM memory cells each include a resistive dielectric material layer sandwiched between two conductive electrodes. The dielectric material is normally insulating. However, by applying the proper voltage across the dielectric layer, a conduction path (typically referred to as a filament) can be formed through the dielectric material layer. Once the filament is formed, it can be “reset” (i.e., broken or ruptured, resulting in a high resistance across the RRAM cell) and set (i.e., re-formed, resulting in a lower resistance across the RRAM cell), by applying the appropriate voltages across the dielectric layer. The low and high resistance states can be utilized to indicate a digital signal of “1” or “0” depending upon the resistance state, and thereby provide a reprogrammable non-volatile memory cell that can store a bit of information.

FIG. 1 shows a conventional configuration of an RRAM memory cell 1. The memory cell 1 includes a resistive dielectric material layer 2 sandwiched between two conductive material layers that form top and bottom electrodes 3 and 4, respectively.

FIGS. 2A-2D show the switching mechanism of the dielectric material layer 2. Specifically, FIG. 2A shows the resistive dielectric material layer 2 in its initial state after fabrication, where the layer 2 exhibits a relatively high resistance. FIG. 2B shows the formation of a conductive filament 7 through the layer 2 by applying the appropriate voltage across the layer 2. The filament 7 is a conductive path through the layer 2, such that the layer exhibits a relatively low resistance across it (because of the relatively high conductivity of the filament 7). FIG. 2C shows the formation of a rupture 8 in filament 7 caused by the application of a “reset” voltage across the layer 2. The area of the rupture 8 has a relatively high resistance, so that layer 2 exhibits a relatively high resistance across it. FIG. 2D shows the restoration of the filament 7 in the area of the rupture 8 caused by the application of a “set” voltage across layer 2. The restored filament 7 means the layer 2 exhibits a relatively low resistance across it. The relatively low resistance of layer 2 in the “formation” or “set” states of FIGS. 2B and 2D respectively can represent a digital signal state (e.g. a “1”), and the relatively high resistance of layer 2 in the “reset” state of FIG. 2C can represent a different digital signal state (e.g. a “0”). The reset voltage (which breaks the filament) can have a polarity opposite that of the filament formation and the set voltages, but it can also have the same polarity. The RRAM cell 1 can repeatedly be “reset” and “set,” so it forms an ideal reprogrammable nonvolatile memory cell.

Formation of the electrodes and switching dielectric material layer can affect performance and stability. Unwanted surface oxidation on the bottom electrode can affect cell performance, and cause cell failure due to parasitic set problems and cell switching. If the bottom electrode surface is too rough, it can degrade cell switching stability. Large cell to cell variations can be caused by other process non-uniformities, which can adversely affect performance and stability. There is a need for an improved methodology for fabricating RRAM cells.

### BRIEF SUMMARY OF THE INVENTION

The aforementioned problems and needs are addressed a method of forming a memory device that includes forming a first layer of conductive material having opposing upper and lower surfaces, forming a layer of amorphous silicon on the upper surface of the first layer of conductive material, stripping away the layer of amorphous silicon, wherein some of the amorphous silicon remains in the upper surface of the first layer of conductive material, forming a layer of transition metal oxide material on the upper surface of the first layer of conductive material, and forming a second layer of conductive material on the layer of transition metal oxide material.

Other objects and features of the present invention will become apparent by a review of the specification, claims and appended figures.

### BRIEF DESCRIPTION OF THE DRAWINGS

FIG. 1 is a side cross sectional view of a conventional RRAM memory cell.

FIG. 2A is a side cross sectional view of a conventional RRAM memory cell in its initial state.

FIG. 2B is a side cross sectional view of a conventional RRAM memory cell illustrating the formation of a conductive filament.

FIG. 2C is a side cross sectional view of a conventional RRAM memory cell illustrating the formation of a rupture in the conductive filament.

FIG. 2D is a side cross sectional view of a conventional RRAM memory cell illustrating the restoration of the conductive filament in the area of the rupture.

FIGS. 3A-3H are side cross sectional views illustrating the formation of a RRAM memory cell according to a first embodiment.

FIGS. 4A-4H are side cross sectional views illustrating the formation of a RRAM memory cell according to a second embodiment.

FIGS. 5A-5C are side cross sectional views illustrating the formation of a RRAM memory cell according to a third embodiment.

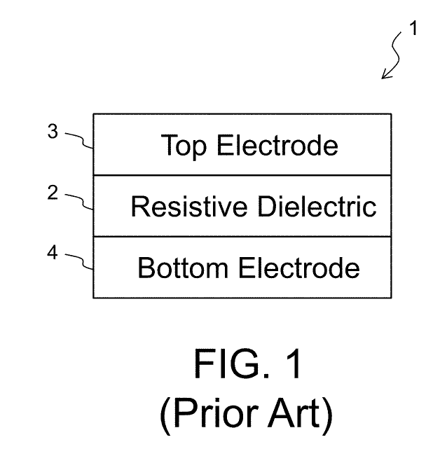

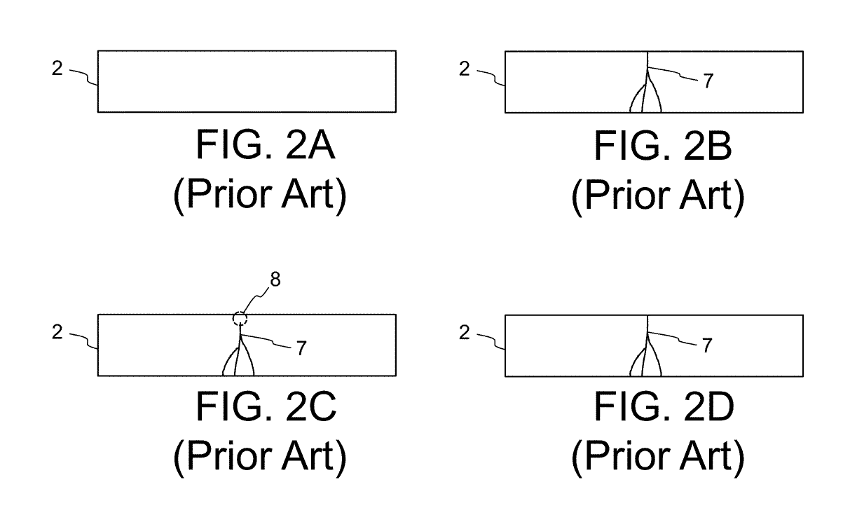

### DETAILED DESCRIPTION OF THE INVENTION

The present invention is a fabrication method that is able to smooth the upper surface of the bottom electrode, and also provide a surface with stable material that is hard to oxidize. There are three embodiments. The first embodiment is a method for standard electrode materials (TiN, TaN, HfN, TiAlN, etc) that can be etched easily in a standard fab. The second embodiment is a method for integrating top electrode metals that are hard to etch (Pt, Ni, etc), and using a replacement process to avoid the etching of these metals. The third embodiment is a method for integrating the bottom electrode metals that are hard to etch.

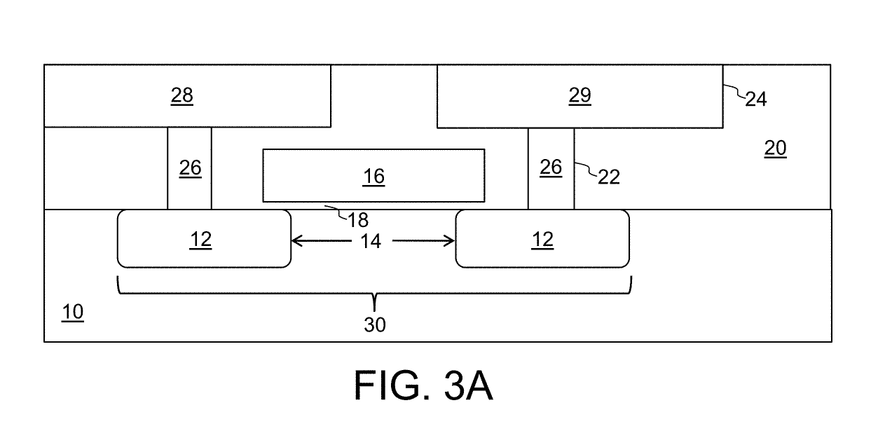

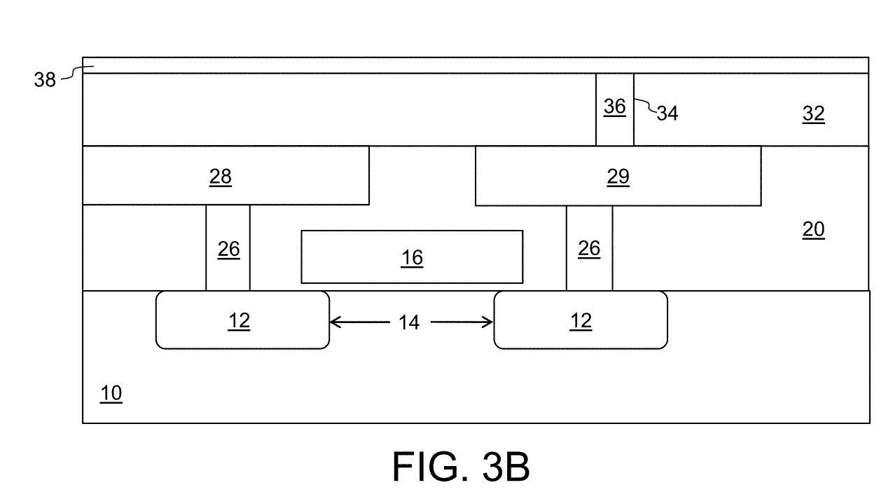

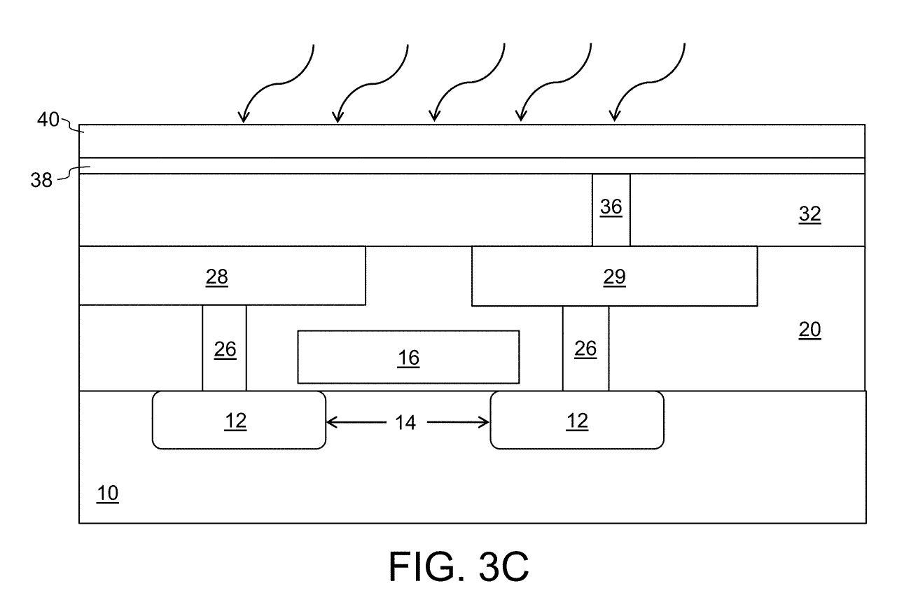

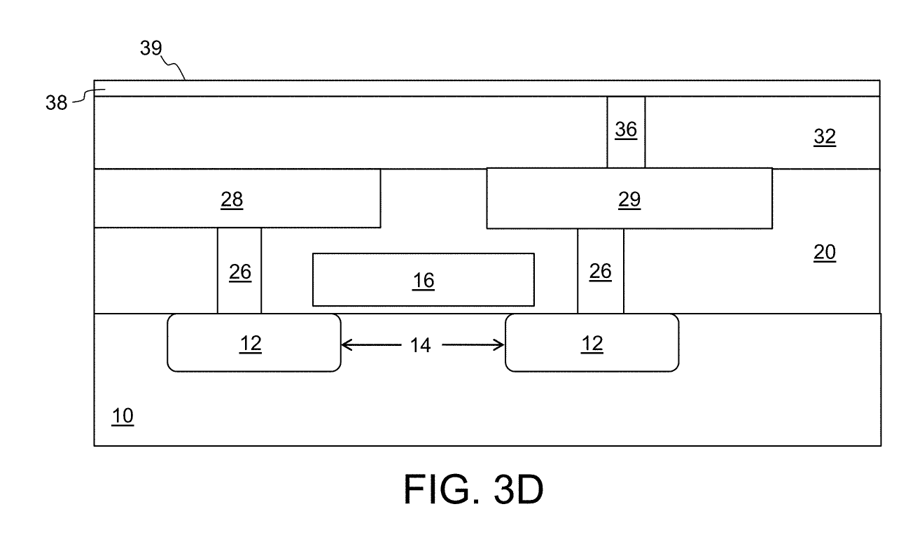

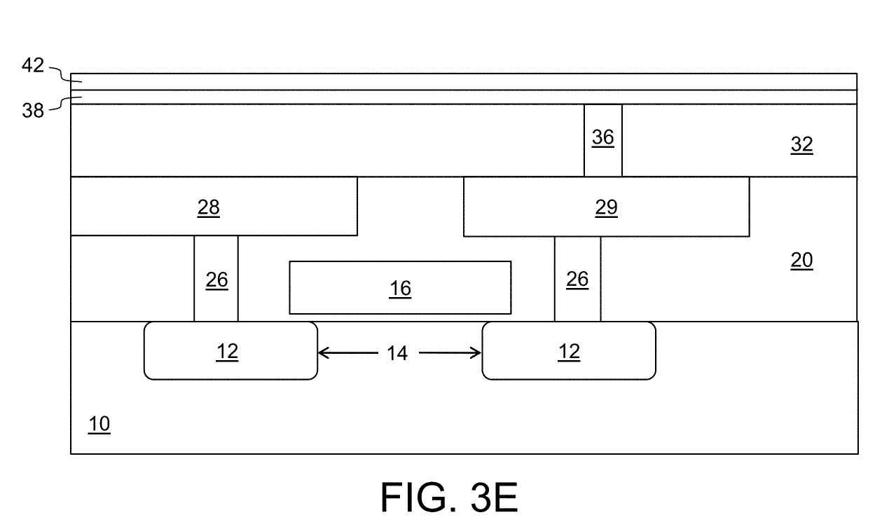

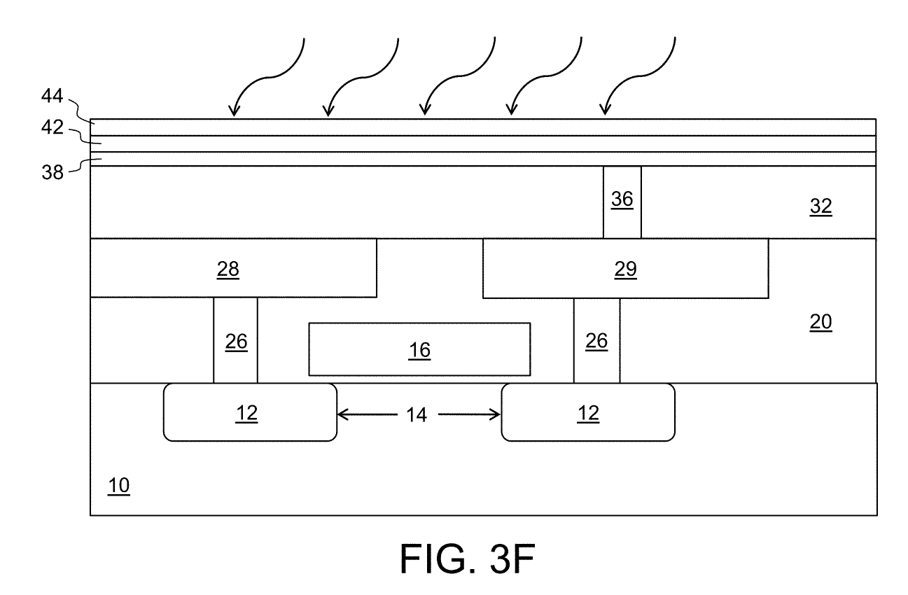

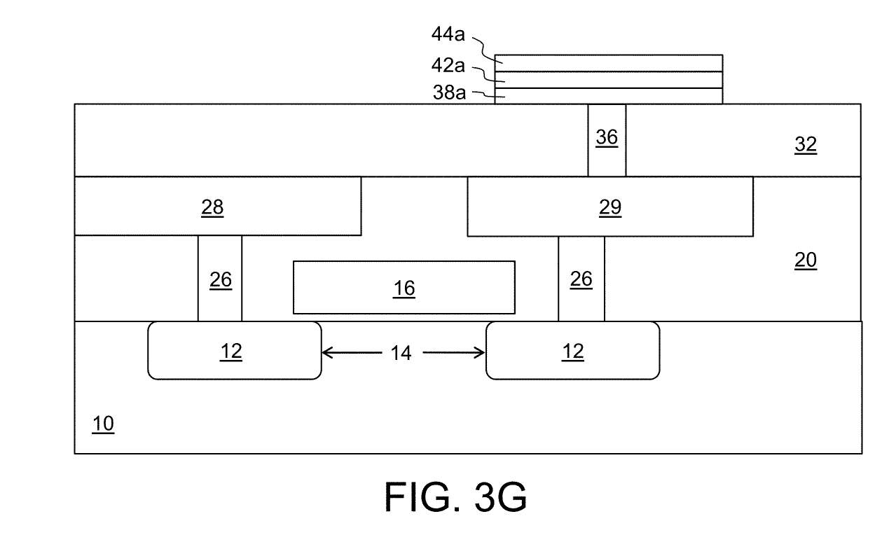

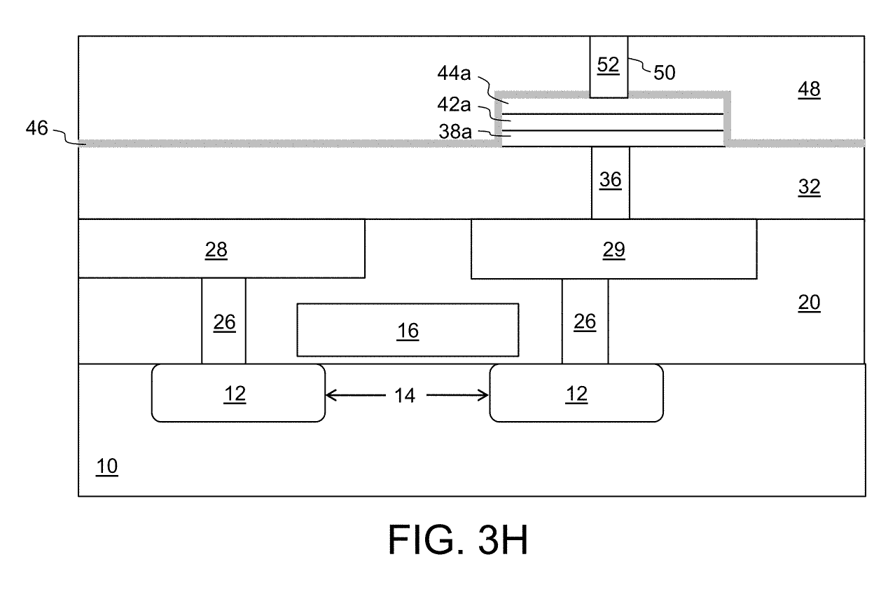

The first embodiment is shown in FIGS. 3A-3H, and starts by forming the structure shown in FIG. 3A. Specifically, a pair of n+ (e.g., first conductivity type) regions 12 are formed in a p-type (e.g., second conductivity type) silicon substrate 10 (e.g., by implantation), which define a channel region 14 there between in the substrate 10. One of the n+ regions is the source (e.g., the n+ region on the left in FIG. 3A), and the other n+ region is the drain (e.g., the n+ region on the right in FIG. 3A). A word line gate 16 (e.g., made of polysilicon) is formed over and insulated from channel region 14 of the substrate 10. Word line gate formation can include formation of an oxide insulation layer 18 (gate oxide) on the substrate, followed by polysilicon deposition on the oxide layer 18, followed by a photolithography and etch process (e.g. photo resist deposition, exposure and selective removal, followed by poly etch) that selectively removes the polysilicon layer except for that portion thereof that constitutes word line gate 16. An oxide insulation 20 is then formed over the substrate. Contact holes 22 are formed in oxide 20 by a photolithography and oxide etch process. Contact metal is then deposited to fill contact holes 22 to form contacts 26 that electrically connect to the exposed N+ regions 12. After a chemical mechanical polish (CMP) process, a layer of metal is deposited on the structure, followed by a CMP process. The metal layer is then patterned using a photolithography and metal etch process, leaving a conductive source line 28 in electrical contact with one of the contacts 26 in contact with the source n+ region, and a drain contact 29 in electrical contact with the other one of the contacts 26 which is in contact with the drain n+ region. Additional insulation is deposited to raise oxide 20 even with contacts 28 and 29 (e.g., by oxide deposition and etch). Contacts 26 electrically connect the n+ regions 12 to the source and drain contacts 28/29. The n+ regions 12, channel region 14 and the word line gate 16 form a select transistor 30 for selectively connecting the RRAM cell being formed next. The resulting structure is shown in FIG. 3A.

Additional oxide 32 is formed over upper surfaces of oxide 20 and source and drain contacts 28/29. A photolithographic and etch process is then used to form a contact hole 34 through oxide 32 to expose contact 29. The contact hole 34 is filled with conductive material to form second contact 36. While the figures only show a single second contact 36, there is a second contact 36 extending up from one of the contacts 29 for each of the RRAM memory cells being formed on substrate 10. A conductive layer 38 is formed on the upper surfaces of oxide 32 and second contact 36. Conductive layer 38 is preferably made of TiN, TaN, HfN, TaAlN, Ti, Ta, Pt, Iridium, or Ruthenium. The resulting structure is shown in FIG. 3B.

Conductive layer 38 will eventually be the bottom electrode of the RRAM cell. The treatment of the upper surface of this bottom electrode is now described. An amorphous silicon layer 40 is deposited on the conductive layer 38, and then annealed (e.g., 30 minutes at 500C), as shown in FIG. 3C. The, the amorphous silicon is stripped (e.g., using hot NH4OH at 60C, or TAMH), as shown in FIG. 3D. The formation, annealing and then stripping of the amorphous silicon results in some silicon left in the upper surface 39 of the conductive layer 38. For example, if the conductive layer 38 is TiN, then the upper surface 39 now includes silicon (TiSiN). It has been discovered that the inclusion of silicon results in an upper surface of the conductive layer 38 that is smooth and thermally stable.

A layer of resistive dielectric material 42 is then formed on the upper surface 39 of the conductive layer 38, as shown in FIG. 3E. Preferably, layer 42 is a switching oxide such as a transition metal oxide (e.g., HfO2, Al2O3, TaOx, TiOx, WOx, VOx, CuOx, etc., or multiple layers of such materials). The switching oxide 42 can be a single layer of material, or can additionally include an oxygen scavenger metal such as Ti, or could include multiple sublayers of different oxides and metals such as HfO2/Al2O3, HfO2/Hf/TaOx, HfO2/Ti/TiOx, etc. Layer 42 is then annealed (e.g., RTA, Flash, LSA, etc.). A second conductive layer 44 is formed on layer 42 and then annealed, as shown in FIG. 3F. Second conductive layer 44 can be TiN, TaN, HfN, TaAlN, Ti, Ta, Pt, Iridium, Ruthenium, etc., the formation of which is followed by an anneal (e.g., RTA, LSA, Flash, etc.). A photolithography and etch process is performed (e.g. photo resist deposition, exposure and selective removal, followed by one or more etches), to selectively remove portions of layers 44, 42, and 38. The remaining portions of these layers define top electrode 44a, bottom electrode 38a, with resistive dielectric material (RDM) layer 42a there between, as shown in FIG. 3G (after photo resist removal).

A nitride layer 46 is deposited over and encapsulates the structure. Oxide 48 is formed on the nitride layer 46. A contact hole 50 is formed through the oxide and nitride (exposing the top electrode TE) by a photolithography and etch process. The contact hole 50 is then filled with a conductive material (e.g., by metal deposition and chemical mechanical polish—CMP) to form a third contact 52. The final structure is shown in FIG. 3H.

The RRAM cell includes RDM layer 42a disposed between lower electrode 38a and upper electrode 44a. The performance and stability of the RRAM cell is enhanced because surface oxidation and surface roughness of the upper surface of lower electrode 38a is prevented by the formation and removal of amorphous silicon on that surface before the formation of the RDM layer 42 on that upper surface. Voltages and/or currents are applied to the memory cells by contacts 36 and 52. Voltages and current for contact 36 pass through contact 29, through contact 26, through the select transistor (n+ regions 12, channel 14, gate 16), through the other contact 26, and through source line contact 28.

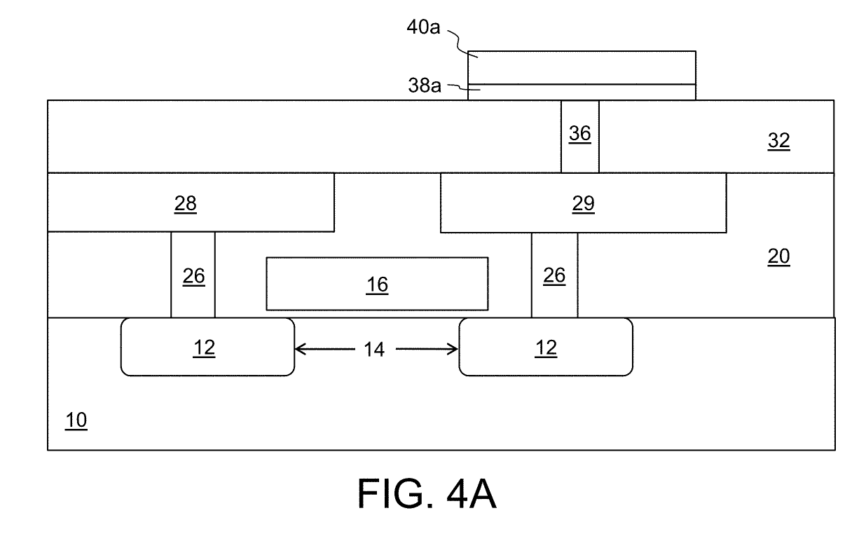

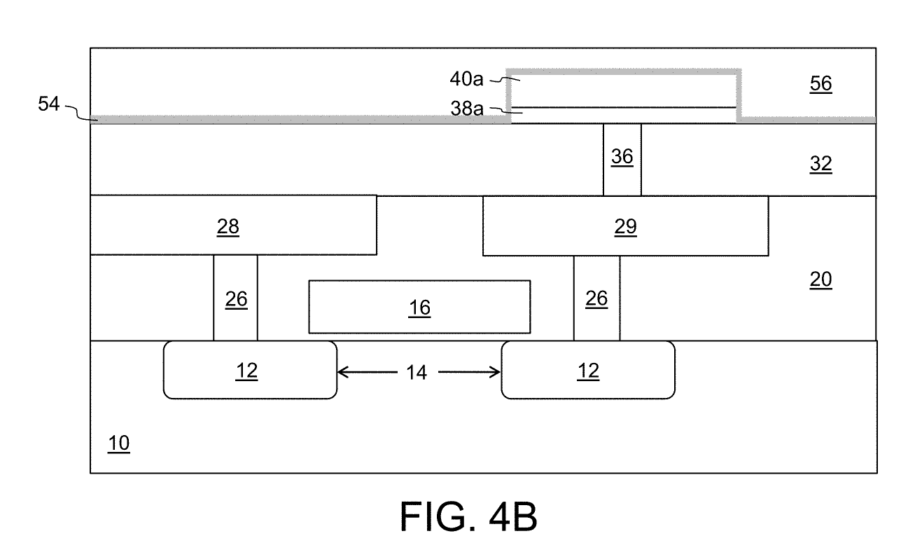

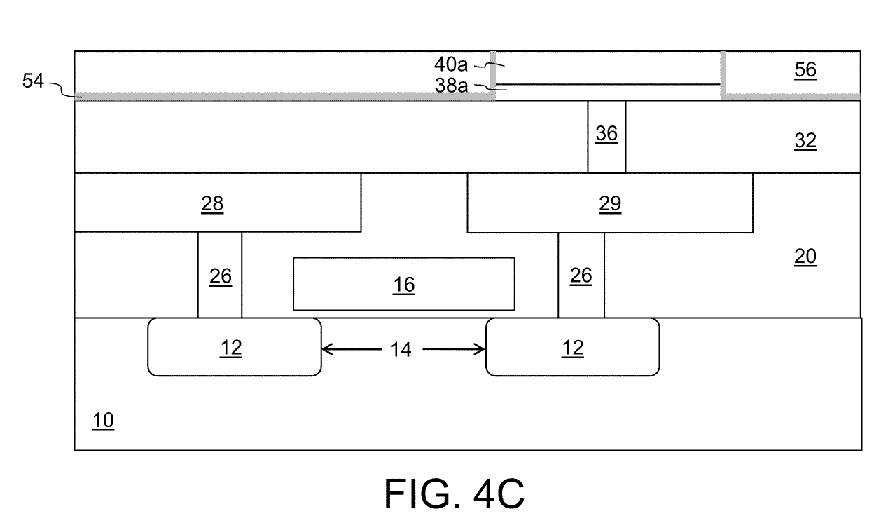

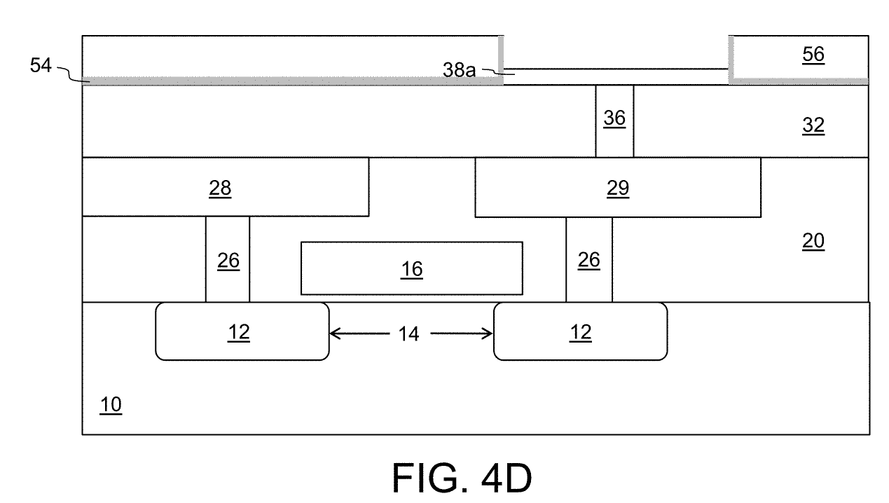

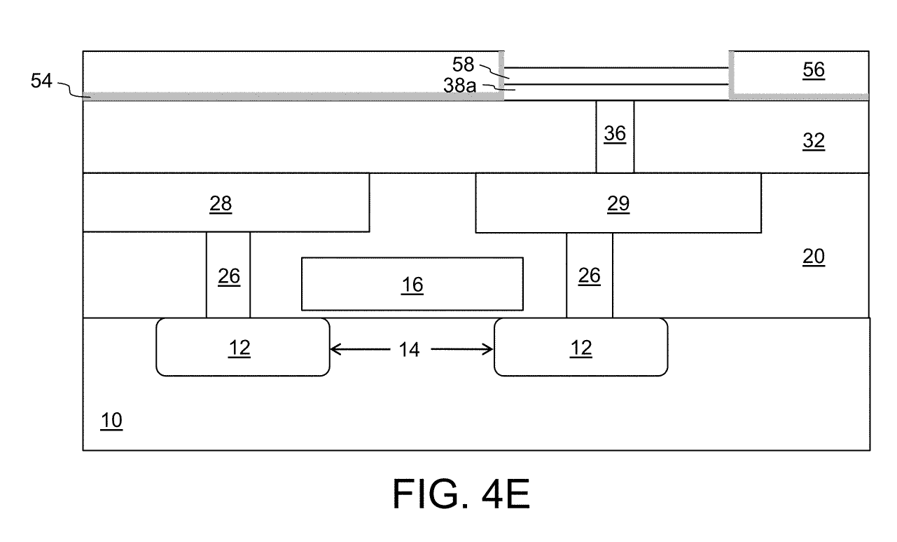

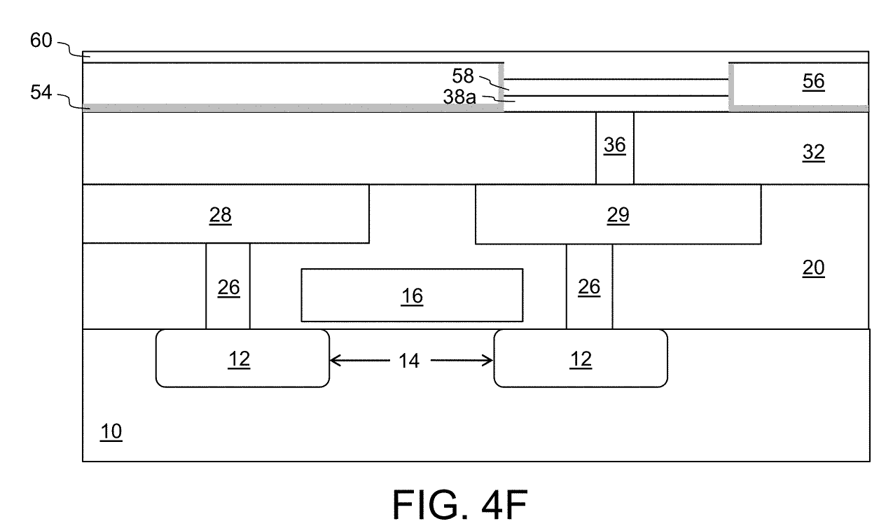

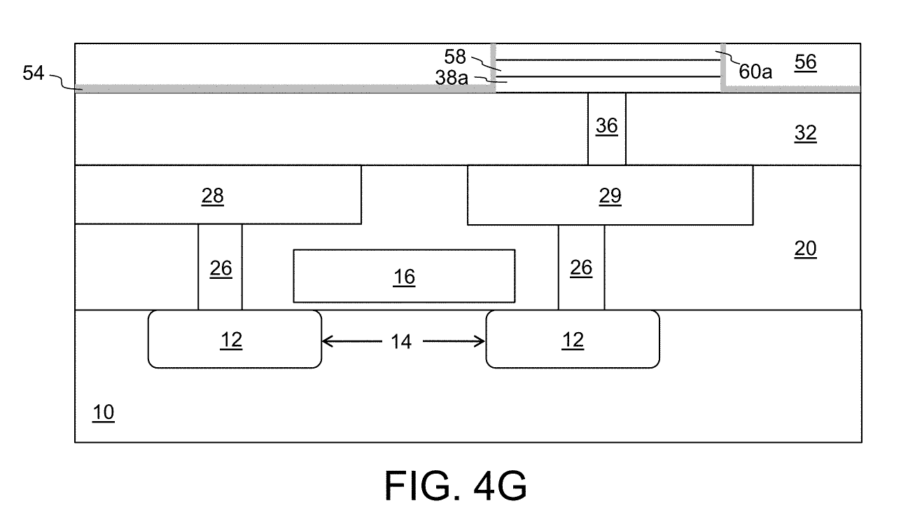

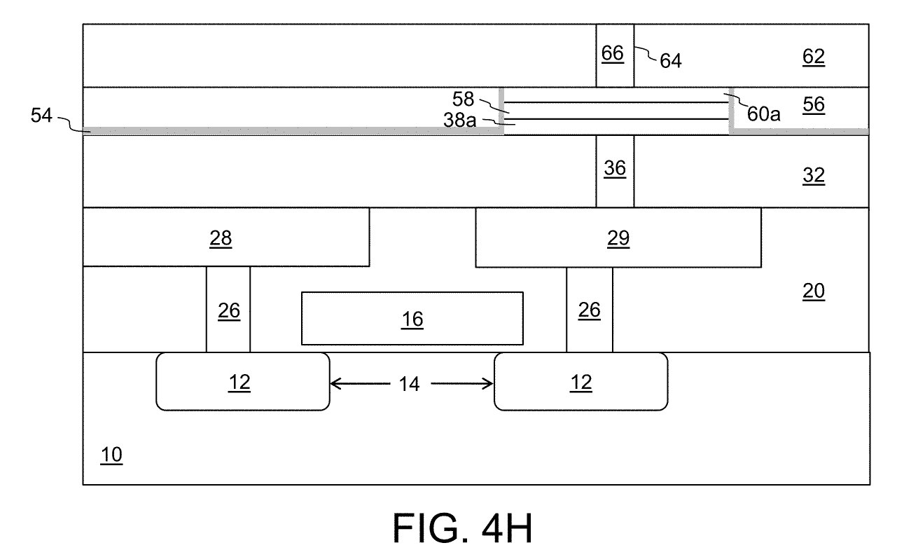

The second embodiment is shown in FIGS. 4A-4H, and starts with the structure shown in FIG. 3C. A photolithography and etch process is performed (e.g. photo resist deposition, exposure and selective removal, followed by one or more etches), which results in defined silicon layer 40a and conductive layer 38a, as shown in FIG. 4A (after photo resist removal). A nitride layer 54 is deposited over and encapsulates the structure. Oxide 56 is then formed on the nitride layer 54, as shown in FIG. 4B. CMP (chemical mechanical polish) is used to remove the upper portion of the oxide 56 and the portion of nitride layer 54 over (and exposing) the amorphous silicon layer 40a (using the silicon layer 40a as an etch stop), as shown in FIG. 4C. The silicon layer 40a is then removed (e.g., using a wet removal etch such as hot NH4OH or TAMH), as shown in FIG. 4D. An RDM layer 58 (e.g. switching oxide) is then formed in the trench (which was left by the removal of the silicon layer 40a, by for example RDM deposition and etch, which is followed by an anneal, as shown in FIG. 4E. Conductive material 60 is deposited on the structure, as shown in FIG. 4F. The conductive material 60 can be a thin layer of conductive material (e.g., Pt, Ni, W, etc.), followed by lower cost metals such as TiN, W, NI, etc. A CMP or dry etch is used to remove the conductive material 60 disposed on oxide 56, leaving a defined conductive layer 60a over the RDM layer 58, as shown in FIG. 4G. An anneal follows. Oxide 62 is formed on the structure. A contact hole 64 is formed through the oxide 62 (exposing layer 60a), and filled with conductive material to form a contact 66. The final structure is shown in FIG. 4H.

This embodiment is advantageous because, for most switching oxides, improved performance and stability can be achieve by forming the upper electrode 60a with Pt or Ni due to their low resistivity, high thermal stability, and good oxygen resistance. However, Pt or Ni cannot be patterned easily using the plasma etching process and usually results in an angled sidewall. In the embodiment of FIGS. 4A-4H, a replacement, single damascene process is used to integrate the Pt or Ni metal as the top electrode of the RRAM stack, without directly etching the material. The embodiment utilizes the CMP process for Pt/Ni, and can use an alumina slurry with H2O2 oxidizer.

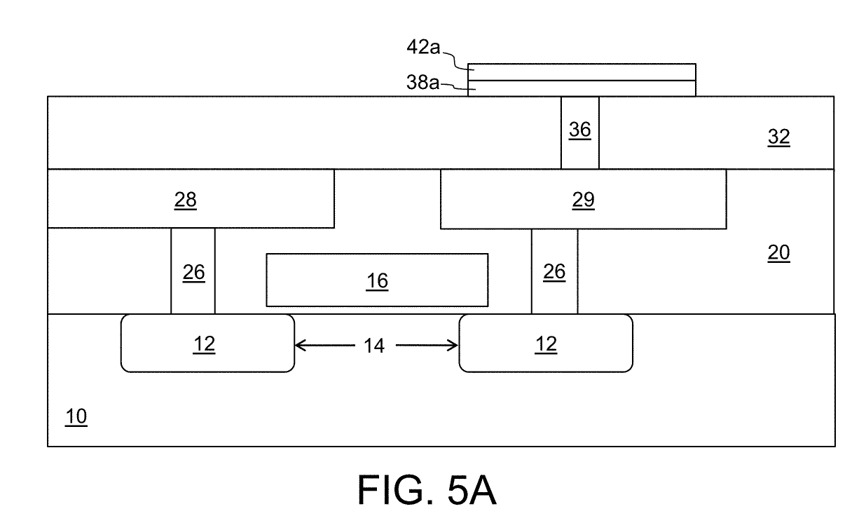

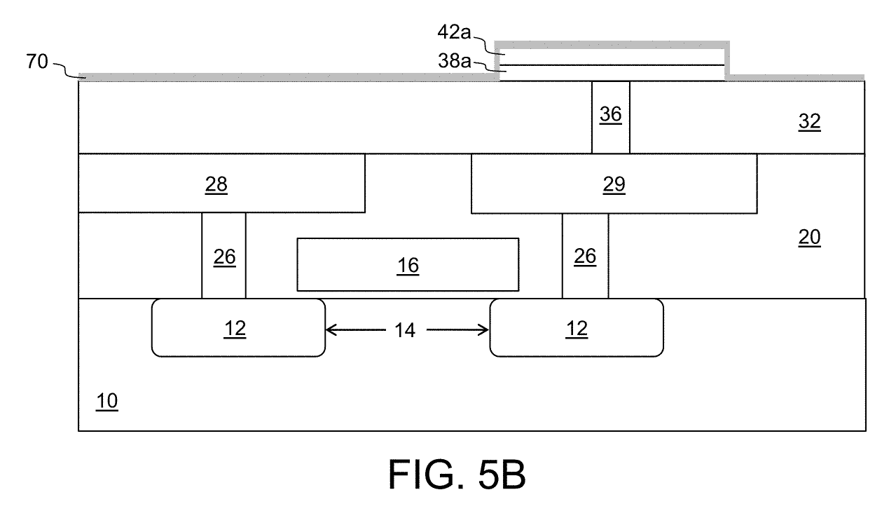

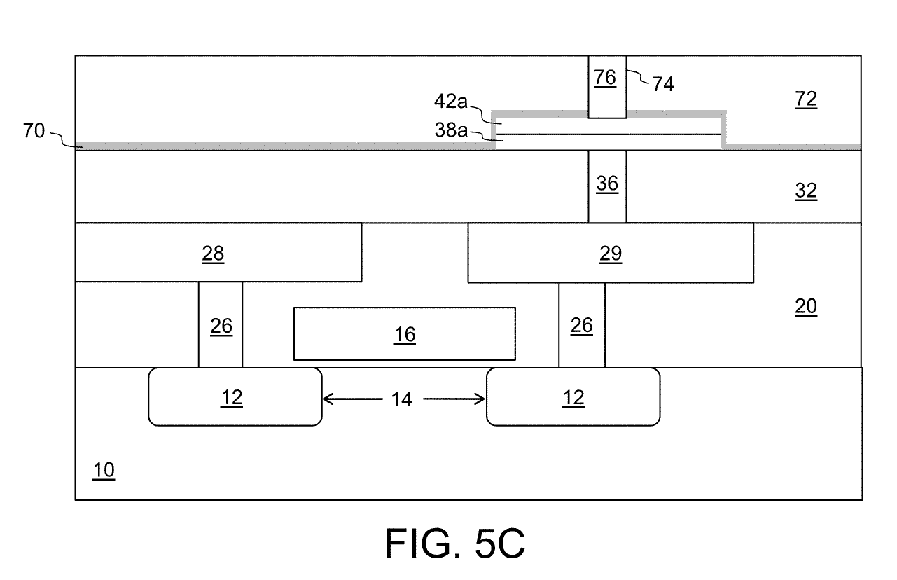

The third embodiment is shown in FIGS. 5A-5C, and starts with the structure shown in FIG. 3E. After the formation of the RDM layer 42, instead of forming the second conductive layer 44 next as is done in the first embodiment, a photolithography and etch process is performed (e.g. photo resist deposition, exposure and selective removal, followed by one or more etches), which results in defined bottom electrode 38a underneath the RDM layer 42a, as shown in FIG. 5A (after photo resist removal). A nitride layer 70 is deposited over and encapsulates the structure, as shown in FIG. 5B. Oxide 72 is formed on the nitride layer 70. A contact hole 74 is formed through the oxide 72 and nitride 70 (exposing the RDM layer 42a). Contact hole 74 is then filled with conductive material (i.e., the layer of conductive material is formed only in the contact hole) to form the top electrode 76. The final structure is shown in FIG. 5C.

This embodiment is advantageous it does not etch both the bottom and top electrodes. Specifically, if a one-step etch is used for the entire stack (bottom and top electrodes plus RCM layer), there is a greater chance of electrical shorts between the top and bottom electrodes due to the metal residues on the cell sidewalls. If the bottom electrode metal is a hard to etch metal (Pt, no volatile byproducts), the bottom electrode etch (ion bombardment) could result in an over-etch for the dielectric oxide. The embodiment of FIGS. 5A-5C solves the above mentioned issues, whereby the switching oxide layer 42a and the bottom electrode 38a can be patterned and etched first, then the top electrode contact 76 can be formed through a top via process that avoids using an etch to define its lateral dimensions.

It is to be understood that the present invention is not limited to the embodiment(s) described above and illustrated herein, but encompasses any and all variations falling within the scope of the claims. For example, references to the present invention herein are not intended to limit the scope of any claim or claim term, but instead merely make reference to one or more features that may be covered by one or more of the claims. Materials, processes and numerical examples described above are exemplary only, and should not be deemed to limit the claims. Further, not all method steps need to necessarily be performed in the exact order illustrated. Single layers of material could be formed as multiple layers of such or similar materials, and vice versa. The terms “forming” and “formed” as used herein shall include material deposition, material growth, or any other technique in providing the material as disclosed or claimed. Lastly, one or more steps in one embodiment can be carried out in the other embodiments, and not all the described steps necessarily are required for any given embodiment.

It should be noted that, as used herein, the terms “over” and “on” both inclusively include “directly on” (no intermediate materials, elements or space disposed there between) and “indirectly on” (intermediate materials, elements or space disposed there between). Likewise, the term “adjacent” includes “directly adjacent” (no intermediate materials, elements or space disposed there between) and “indirectly adjacent” (intermediate materials, elements or space disposed there between), “mounted to” includes “directly mounted to” (no intermediate materials, elements or space disposed there between) and “indirectly mounted to” (intermediate materials, elements or spaced disposed there between), and “electrically coupled” includes “directly electrically coupled to” (no intermediate materials or elements there between that electrically connect the elements together) and “indirectly electrically coupled to” (intermediate materials or elements there between that electrically connect the elements together). For example, forming an element “over a substrate” can include forming the element directly on the substrate with no intermediate materials/elements there between, as well as forming the element indirectly on the substrate with one or more intermediate materials/elements there between.

What is claimed is:

1. A method of forming a memory device, comprising:
forming a first layer of conductive material having opposing upper and lower surfaces;
forming a layer of amorphous silicon on the upper surface of the first layer of conductive material;
stripping away the layer of amorphous silicon, wherein some of the amorphous silicon remains in the upper surface of the first layer of conductive material;
forming a layer of transition metal oxide material on the upper surface of the first layer of conductive material; and
forming a second layer of conductive material on the layer of transition metal oxide material.

2. The method of claim 1, further comprising:
annealing the amorphous silicon before the stripping.

3. The method of claim 1, further comprising:
forming a first layer of insulation material;
forming a first cavity in the first layer of insulation material; and
forming a first conductive contact in the first cavity;
wherein the first layer of conductive material is formed on the first layer of insulation material and in electrical contact with the first conductive contact.

4. The method of claim 3, further comprising:
forming a second layer of insulation material over the second layer of conductive material;
forming a second cavity in the second layer of insulation material; and
forming a second conductive contact in the second cavity;
wherein the second conductive contact is in electrical contact with the second layer of conductive material.

5. The method of claim 4, wherein the second layer of insulation material is nitride and is formed directly on the second layer of conductive material.

6. The method of claim 4, wherein the second layer of insulation material is oxide.

7. The method of claim 1, wherein the layer of transition metal oxide material includes at least one of HfO2, Al2O3, TaOx, TiOx, WOx, VOx and CuOx.

8. The method of claim 1, wherein the layer of transition metal oxide material includes two or more sublayers of materials each including at least one of HfO2, Al2O3, TaOx, TiOx, WOx, VOx and CuOx.

9. The method of claim 1, further comprising:
forming first and second regions of a first conductivity type in a surface of a substrate of a second conductivity type different than the first conductivity type;
forming a conductive gate disposed over and insulated from the substrate, and between the first and second regions;
electrically coupling the first layer of conductive material to the second region.

10. The method of claim 1, further comprising:
performing one or more etch processes that selectively remove portions of the second layer of conductive material, the layer of transition metal oxide material, and the first layer of conductive material, leaving a block of the first layer of conductive material, a block of the layer of transition metal oxide material on the block of the first layer of conductive material, and a block of the second layer of conductive material on the block of the layer of transition metal oxide material.

11. The method of claim 1, further comprising:
before the stripping away of the layer of amorphous silicon, performing one or more etch processes that selectively remove portions of the layer of amorphous silicon and the first layer of conductive material, leaving a block of the first layer of conductive material and a block of the amorphous silicon on the block of the first layer of conductive material;
forming insulation material alongside the block of the first layer of conductive material and the block of amorphous silicon;
wherein the stripping of the layer of amorphous silicon is performed after the forming of the insulation material.

12. The method of claim 11, wherein:
the stripping of the layer of amorphous silicon results in a trench extending into the insulation material;
the layer of transition metal oxide material is formed in the trench; and
the second layer of conductive material is formed in the trench.

13. The method of claim 1, further comprising:
before the forming of the second layer of insulation material, performing one or more etch processes that selectively remove portions of the layer of transition metal oxide material and the first layer of conductive material, leaving a block of the first layer of conductive material and a block of the layer of transition metal oxide material on the block of the first layer of conductive material;
forming insulation material alongside and over the block of the first layer of conductive material and the block of the layer of transition metal oxide material;
forming a hole in the insulation material that extends to and exposes the block of the layer of transition metal oxide material;
wherein the second layer of conductive material is formed in the hole.

14. The method of claim 13, wherein the insulation material is nitride and is formed directly on the block of the layer of transition metal oxide material.

15. The method of claim 13, wherein the insulation material is oxide.
